(19) United States
(12) Patent Application Publication
(10) Pub. No.: US 2022/0302155 A1
(43) Pub. Date: Sep. 22, 2022

(54) SEMICONDUCTOR MEMORY DEVICE

(71) Applicant: Kioxia Corporation, Tokyo (JP)

(72) Inventors: Ayumi WATARAI, Ama (JP); Osamu MATSUURA, Kuwana (JP); Taro KUSUMOTO, Yokkaichi (JP); Sota MATSUMOTO, Yokkaichi (JP)

(73) Assignee: Kioxia Corporation, Tokyo (JP)

(21) Appl. No.: 17/446,865

(22) Filed: Sep. 3, 2021

(30) Foreign Application Priority Data
Mar. 22, 2021 (JP) 2021-047657

(51) Int. Cl. H01L 27/11578; H01L 27/11519; H01L 27/11565; H01L 27/11551

(52) U.S. Cl. CPC H01L 27/11578; H01L 27/11519; H01L 27/11565; H01L 27/11551

(57) ABSTRACT

A semiconductor memory device according to an embodiment includes: a first stacked body in which a plurality of conductive layers and a plurality of insulating layers are alternately stacked one by one, the first stacked body including a stair portion processed into a stair shape extending in a first direction such that the plurality of conductive layers forms terrace surfaces; an insulating film covering an upper portion of the first stacked body including the stair portion; and a first plate-like portion that extends in the first direction in the stair portion and penetrates the first stacked body, the first plate-like portion including a plurality of bridge portions that are arranged locally on an upper end portion side and intermittently in the first direction to couple parts of the insulating film arranged on both sides of the first plate-like portion to each other.

### CROSS-REFERENCE TO RELATED APPLICATIONS

This application is based upon and claims the benefit of priority from Japanese Patent Application No. 2021-047657, filed on Mar. 22, 2021; the entire contents of which are incorporated herein by reference.

### FIELD

Embodiments described herein relate generally to a semiconductor memory device.

### BACKGROUND

Examples of a semiconductor memory device having a three-dimensional structure include one having a stacked body in which a plurality of conductive layers and a plurality of insulating layers are alternately stacked one by one, and memory pillars penetrating the stacked body along the stacking direction of the stacked body, in which a plurality of memory cells is formed in portions where the conductive layers face the memory pillars. In addition, in such a semiconductor memory device, the conductive layer functions as a word line, and in order to connect a contact to the conductive layer as the word line, a stair portion is provided in which the stacked body is processed into a stair shape such that the conductive layers become terrace surfaces.

Such a structure is realized through various processes such as forming holes and grooves in the insulating layers and sacrificial layers each formed of a different material, replacing the sacrificial layers with the conductive layers, and forming various protective layers.

In the course of such processes, various stresses act on each layer due to differences in material and thickness. Moreover, the number of the conductive layers tends to increase due to an increase in memory capacity, and as a result, the stacked body also becomes thick. This can cause a situation in which the stress acting on each layer increases and the layer bends or tilts, and in some cases no subsequent process can be performed.

### BRIEF DESCRIPTION OF THE DRAWINGS

FIG. 1 is a partial top view of a semiconductor memory device according to a first embodiment;

FIG. 2 is a partial cross-sectional view taken along line L1-L1 of FIG. 1;

FIG. 3A is a partial cross-sectional view taken along line L2-L2 of FIG. 1;

FIG. 3B is a partial cross-sectional view taken along line L3-L3 of FIG. 1;

FIGS. 4Aa to 4Bc are partial cross-sectional views for explaining a method for forming a stair area of the semiconductor memory device according to the first embodiment;

FIGS. 5Ad to 5Bf are partial cross-sectional views for explaining the method for forming the stair area of the semiconductor memory device according to the first embodiment;

FIGS. 6Ag to 6Bi are partial cross-sectional views for explaining the method for forming the stair area of the semiconductor memory device according to the first embodiment;

FIGS. 7Aj to 7Bk are partial cross-sectional views for explaining the method for forming the stair area of the semiconductor memory device according to the first embodiment;

FIGS. 8Aa to 8Bb are partial cross-sectional views for explaining effects exerted by the semiconductor memory device according to the first embodiment;

FIGS. 9Aa to 9Bc are partial cross-sectional views for explaining a method for forming a stair area of a semiconductor memory device according to a comparative example;

FIGS. 10A to 10C are partial cross-sectional views of a stair area at three positions of different heights of terrace surfaces at a stair portion of a semiconductor memory device according to a first modification of the first embodiment;

FIGS. 11A to 11F are partial cross-sectional views for explaining a method for forming the stair area of the semiconductor memory device according to the first modification of the first embodiment;

FIGS. 12G to 12I are partial cross-sectional views for explaining the method for forming the stair area of the semiconductor memory device according to the first modification of the first embodiment;

FIG. 13A is a partial top view of a semiconductor memory device according to a second modification of the first embodiment;

FIG. 13B is a partial cross-sectional view of the semiconductor memory device according to the second modification of the first embodiment;

FIGS. 14A to 14F are partial cross-sectional views for explaining a method for forming a stair area of a semiconductor memory device according to a second embodiment;

FIGS. 15G to 15I are partial cross-sectional views for explaining the method for forming the stair area of the semiconductor memory device according to the second embodiment;

FIG. 16 is a partial top view of the semiconductor memory device according to the second embodiment; and

FIG. 17 is a partial top view of a semiconductor memory device according to a modification of the second embodiment.

### DETAILED DESCRIPTION

A semiconductor memory device according to an embodiment includes a first stacked body, an insulating film, and a first plate-like portion. In the first stacked body, a plurality of first conductive layers and a plurality of first insulating layers are alternately stacked one by one. In addition, the first stacked body includes a stair portion processed into a stair shape extending in a first direction intersecting with a stacking direction of the first stacked body such that the plurality of first conductive layers forms a plurality of terrace surfaces. The insulating film covers an upper portion of the first stacked body including the stair portion. The first plate-like portion extends in the first direction in the stair portion and penetrates the first stacked body in the stacking direction. In addition, the first plate-like portion includes a plurality of bridge portions that are arranged locally on an upper end portion side and intermittently in the first direction to couple parts of the insulating film arranged on both sides of the first plate-like portion to each other.

Hereinafter, non-limiting exemplary embodiments of the present invention will be described with reference to the accompanying drawings. In all the accompanying drawings, the same or corresponding members or parts are denoted by the same or corresponding reference signs, and duplicate description is omitted. In addition, the drawings are not intended to illustrate the relative ratios between members or parts or between the thicknesses of various layers, and therefore specific thicknesses and dimensions may be determined by those skilled in the art in light of the following non-limiting embodiments.

### First Embodiment

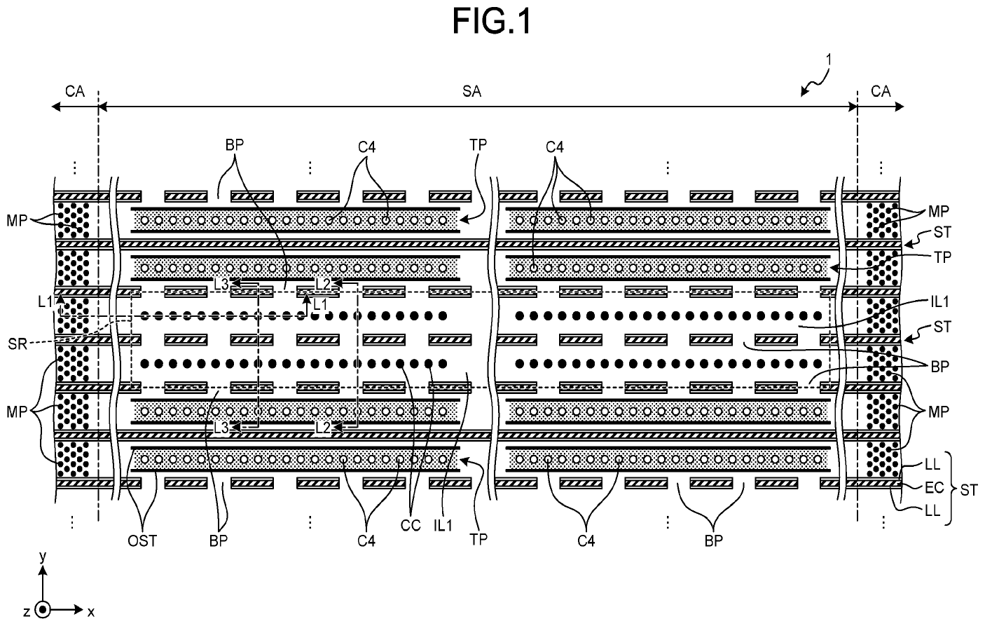

With reference to FIG. 1, a semiconductor memory device according to a first embodiment will be described. A semiconductor memory device 1 according to the present embodiment includes a substantially rectangular substrate formed of a semiconductor such as silicon, a peripheral circuit unit formed on the substrate, and a cell array area and a stair area formed on the peripheral circuit unit. FIG. 1 is a partial top view of the semiconductor memory device according to the first embodiment, and illustrates a part of each of a cell array area CA and a stair area SA of the semiconductor memory device 1. An upper wiring layer including upper wiring, plugs, and the like is provided on the cell array area CA and the stair area SA, but illustration thereof is omitted in FIG. 1.

The cell array area CA includes a first stacked body in which a plurality of conductive layers and a plurality of insulating layers are alternately stacked one by one, and a plurality of memory pillars MP penetrating the first stacked body in a z direction. The memory pillars MP are arranged in a lattice pattern in an xy plane in the drawing, and extend in the z direction in the drawing.

The stair area SA is sandwiched between the cell array areas CA on both sides, for example, in an x direction, and includes a stair portion SR and through connecting portions TP. In the present embodiment, each of the stair portion SR and the through connecting portion TP has a predetermined length in the x direction. In addition, one stair portion SR and two through connecting portions TP are alternately arranged in a y direction. In the stair area SA, the first stacked body extends at least partially from the cell array areas CA on both sides of the stair area SA. In the stair portion SR, the first stacked body is processed into a stair shape such that each of the plurality of conductive layers forms a terrace surface (tread surface), and a first interlayer insulating film IL1 is formed above the first stacked body. The first interlayer insulating film IL1 may be formed of, for example, silicon oxide. In addition, in the stair portion SR, contacts CC that penetrate the first interlayer insulating film IL1 to be connected to the terrace surfaces are provided.

The through connecting portion TP includes two plate-like bodies OST. These plate-like bodies OST are shorter than a plate-like portion ST described later, locally extend in the x direction, and extend in the z direction to penetrate the first stacked body. A second stacked body, in which a plurality of insulating layers and a plurality of insulating layers different from the above insulating layers are alternately stacked one by one, is provided between the two plate-like bodies OST. In addition, in the through connecting portion TP, through contacts C4 that penetrate the second stacked body to reach the peripheral circuit unit is provided.

In addition, in the semiconductor memory device 1, a plurality of plate-like portions ST that divide the cell array area CA and the stair area SA are provided. The plate-like portions ST traverse the cell array area CA and the stair area SA in the x direction, extend in the z direction in the drawing, and terminate in a source line described later. In the present embodiment, the plate-like portion ST includes a liner layer LL and a conductive portion EC inside the liner layer LL. The liner layer LL may be formed of an insulating material such as silicon oxide, and the conductive portion EC may be formed of a metal such as tungsten or molybdenum. The conductive portion EC is connected to the source line described later, so as to function as a source contact. Note that the plate-like portion ST may be formed of an insulating material, such as silicon oxide, as a whole.

In the stair area SA, bridge portions BP are provided in at least the plate-like portion ST whose one side the stair portion SR is provided on, among the plurality of plate-like portions ST. In other words, the bridge portions BP are not provided in at least the plate-like portion ST arranged between the two adjacent through connecting portions TP in the present embodiment. The bridge portions BP are provided intermittently in a longitudinal direction of the plate-like portion ST (x direction) and locally on the upper end portion sides of the plate-like portions ST. As a result, the parts of the first interlayer insulating film IL1 arranged on both sides of the plate-like portion ST are coupled via the bridge portion BP.

Note that the length in the x direction and the length in the z direction (depth) of the bridge portion BP, the interval between the adjacent bridge portions BP, the number of the bridge portions BP, and the like may be appropriately determined according to, for example, the number of layers of the first stacked body described later. In addition, in the present embodiment, the bridge portions BP are provided in the plate-like portion ST in the stair area SA, and are not provided in the cell array area CA.

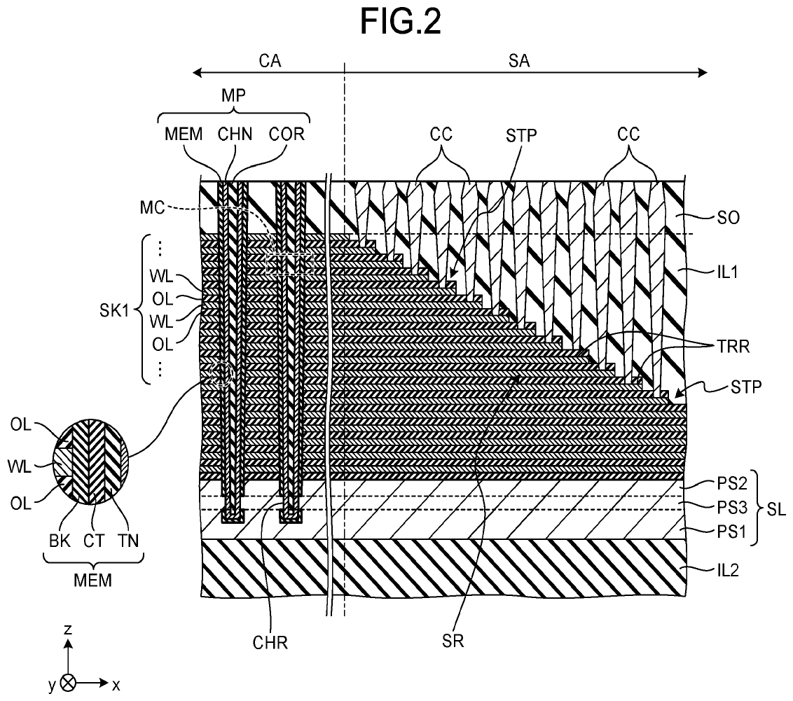

Next, the memory pillar MP, the stair portion SR, and the like will be described with reference to FIG. 2. FIG. 2 is a partial cross-sectional view taken along line L1-L1 of FIG. 1; As illustrated, a first stacked body SK1 in which a plurality of conductive layers WL and a plurality of insulating layers OL are alternately stacked one by one is formed on a source line SL. The source line SL includes a first layer PS1, a third layer PS3, and a second layer PS2 each formed of, for example, conductive polycrystalline silicon. The source line SL is formed on a second interlayer insulating film IL2 that is a part of a peripheral circuit unit described later.

As illustrated in FIG. 2, the cell array area CA is provided with the memory pillars MP that penetrate the first stacked body SK1 in the stacking direction of the first stacked body SK1, which is the z direction, and terminate in the source line SL. The memory pillar MP has a bottomed substantially cylindrical shape, and includes a core layer COR, a channel layer CHN, and a memory film MEM that are concentrically formed from the center toward the outside. That is, the channel layer CHN is formed to cover a side wall and a bottom surface of the core layer COR formed at the central portion of the memory pillar MP. The memory film MEM is formed to cover a side wall and a bottom surface of the channel layer CHN. In the source line SL, however, the memory film MEM is not formed around the channel layer CHN at the position of the third layer PS3, so that the channel layer CHN is in direct contact with the third layer PS3.

Here, the core layer COR may be formed of, for example, silicon oxide, and the channel layer CHN may be formed of, for example, conductive polycrystalline silicon or amorphous silicon. In addition, as illustrated in FIG. 2, the memory film MEM includes a tunnel insulating layer TN, a charge storage layer CT, and a block insulating layer BK sequentially formed along a direction from the center of the memory pillar MP toward the outside. The tunnel insulating layer TN and the block insulating layer BK may be formed of, for example, silicon oxide, and the charge storage layer CT may be formed of, for example, silicon nitride.

Memory cells MC are formed in portions where the conductive layers WL in the first stacked body SK1 face the memory film MEM of the memory pillar MP. In this case, the conductive layers WL functions as word lines. However, portions, where the uppermost conductive layer WL and the lowermost conductive layer WL among the plurality of conductive layers WL face the memory pillar MP, function as select transistors. That is, the uppermost conductive layer WL in the first stacked body SK1 corresponds to a drain-side select gate line, while the lowermost conductive layer WL corresponds to a source-side select gate line.

In addition, in the memory pillar MP, the memory film MEM is not provided in a range corresponding to the space between the lower surface and the upper surface of the third layer PS3 in the source line SL, as described above. Therefore, the channel layer CHN constitutes the outer surface of the memory pillar MP in the range. And, the channel layer CHN is in contact with the third layer PS3. As a result, the channel layer CHN and the source line SL are electrically connected. That is, the source line SL functions as a source for the memory cells MC formed in the memory pillar MP as a whole. Since the outer peripheral surface of the channel layer CHN is in contact with the third layer PS3, the contact area between the channel layer CHN and the third layer PS3 can be increased, and therefore a contact resistance can be reduced.

Note that on the memory pillar MP, a plug (not illustrated) to be connected to the channel layer CHN of the memory pillar MP is provided. In addition, the plug is connected to upper wiring (not illustrated), and the upper wiring may be connected to the through contact C4 that penetrates the second stacked body described later and is connected to the peripheral circuit unit.

The stair portion SR has a plurality of steps STP, and each step STP is constituted by a set of the conductive layer WL and the insulating layer OL. Above the stair portion SR, the first interlayer insulating film IL1 and the insulating film SO are formed in this order. The first interlayer insulating film IL1 is formed of an insulating material such as silicon oxide, similarly to the insulating material of the insulating layer OL, and therefore the insulating layer OL and the first interlayer insulating film IL1 are substantially integrated. The conductive layers WL extend in the x direction from the cell array area CA to the stair area SA, and their extension lengths become shorter as the conductive layer WL is located at a higher position, that is, located farther from the source line SL. As a result, in the stair portion SR, the conductive layers WL descend in a direction away from the cell array area CA, and the conductive layer WL forms a substantial terrace surface TRR of each step STP.

Note that the insulating film SO is also formed of the same insulating material as the first interlayer insulating film IL1, and is substantially integrated with the first interlayer insulating film IL1. In the following description, the insulating film SO and the first interlayer insulating film IL1 may be collectively referred to as the first interlayer insulating film IL1.

The contact CC penetrating the first interlayer insulating film IL1 is connected to the terrace surface TRR of the conductive layer WL. The contact CC can be formed of a metal such as tungsten or molybdenum. The contact CC is connected to the peripheral circuit unit described later by the non-illustrated upper wiring and through contact C4, so that a predetermined voltage is applied from the peripheral circuit unit to the memory cell MC via the conductive layer WL as a word line. In this case, through the first stacked body SK1 extending along the plate-like portion ST, the plurality of conductive layers WL in the first stacked body SK1 is commonly used as word lines between the cell array areas CA arranged on both sides, in the x direction, of the stair portion SR.

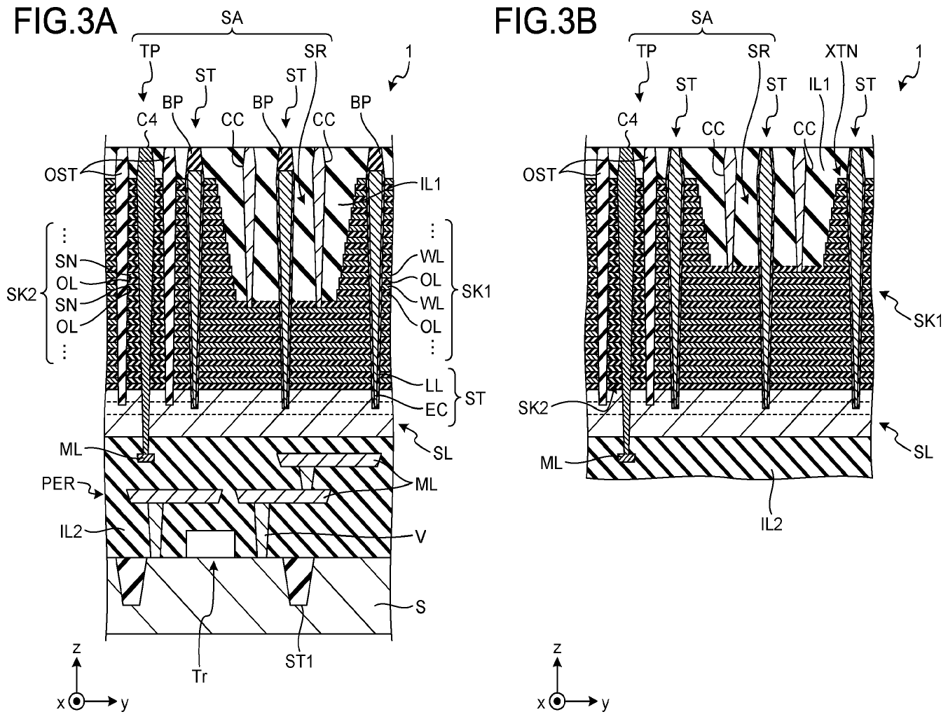

Next, the stair area SA will be described with reference to FIGS. 3A and 3B. FIG. 3A is a partial cross-sectional view taken along line L2-L2 of FIG. 1, and FIG. 3B is a partial cross-sectional view taken along line L3-L3 of FIG. 1. That is, the former is a partial cross-sectional view at a position where the bridge portions BP are provided, while the latter is a partial cross-sectional view at a position where no bridge portion BP is provided.

As illustrated in FIG. 3A, a transistor Tr separated by element isolation portions STI is formed on a surface layer of a semiconductor substrate S (hereinafter, simply referred to as a substrate S) such as a silicon wafer. The second interlayer insulating film IL2, formed of an insulating material such as silicon oxide, is formed on the transistor Tr and the substrate S, and a via V and wiring ML to be connected to a gate electrode of the transistor Tr and the like are provided in the second interlayer insulating film IL2. The transistor Tr, the via V, the wiring ML, and the second interlayer insulating film IL2 constitute a peripheral circuit unit PER that controls the memory cells MC (FIG. 2). The peripheral circuit unit PER may include, for example, a row decoder that identifies an area including the memory cell MC to be operated, and a sense amplifier circuit that senses data held by the memory cell MC. Note that in FIG. 3B and subsequent drawings, illustration of a part of the peripheral circuit unit PER is omitted for convenience.

The source line SL and the first stacked body SK1 are formed in this order over the peripheral circuit unit PER. As described above, the first stacked body SK1 has the stair portion SR, and the first interlayer insulating film IL1 is formed above the stair portion SR. The plate-like portion ST penetrates the first interlayer insulating film IL1 and the first stacked body SK1 to terminate in the source line SL. The bridge portion BP is provided in the upper end portion of the plate-like portion ST, and the liner layer LL and the conductive portion EC inside the liner layer LL are formed under the bridge portion BP. Similarly to the first interlayer insulating film IL1, the bridge portion BP may be formed of, for example, silicon oxide. On the other hand, in FIG. 3B, the bridge portion BP is not provided, and the upper end surface of the plate-like portion ST is substantially the same as the surface of the first interlayer insulating film IL1.

In addition, the contacts CC penetrating the first interlayer insulating film IL1 to be connected to the conductive layer WL as the terrace surface of the stair portion SR are provided on both sides of the central plate-like portion ST. The contact CC is connected to the non-illustrated upper wiring via a non-illustrated plug.

In addition, the through connecting portion TP is arranged on the opposite side of the stair portion SR with respect to the plate-like portion ST on the left side of the drawing. Note that the through connecting portion TP is similarly arranged also on the opposite side of the stair portion SR with respect to the plate-like portion ST on the right side of the drawing (see FIG. 1). On the other hand, in the vicinities, on the stair portion SR side, of these left side and right side plate-like portions ST, the plurality of conductive layers WL of the first stacked body SK1 extends along the plate-like portion ST and in the x direction without being processed into a step shape. In other words, an extension portion XTN in which the plurality of conductive layers WL remains as a whole extends in an area between the step shape processed along the x direction, and the plate-like portion ST extending, along the stair portion SR, in the x direction.

The through connecting portion TP includes two plate-like bodies OST, the second stacked body SK2 provided therebetween, and the through contact C4 penetrating the first interlayer insulating film IL1 and the second stacked body SK2. The plate-like body OST is formed of, for example, silicon oxide, extends from the upper surface of the first interlayer insulating film IL1, and terminates in the source line SL. The second stacked body SK2 includes a plurality of sacrificial layers SN and a plurality of insulating layers OL alternately stacked one by one. The sacrificial layer SN is formed of silicon nitride, and the insulating layer OL is formed of silicon oxide. Therefore, the second stacked body SK2 has an insulating property as a whole, and therefore the through contact C4 penetrating the second stacked body SK2 is insulated from the conductive layers WL.

The through contact C4 is formed of a metal such as tungsten or molybdenum, and is connected, at the upper end, to the non-illustrated upper wiring via a non-illustrated plug. In addition, the lower end of the through contact C4 is connected to the wiring ML in the peripheral circuit unit PER. As a result, the peripheral circuit unit PER and the conductive layer WL can be electrically connected to each other via the through contact C4, the plug, upper layer wiring, the plug, and the contact CC.

Note that in FIGS. 2 to 3B, the conductive layers WL or the sacrificial layers SN and the insulating layers OL having appropriate numbers of layers for explanation are illustrated, but the number of the conductive layers WL may be appropriately determined without being limited to the illustrated example. For example, 48 layers, 64 layers, or 96 layers of the conductive layers may be formed. In addition, the number of the conductive layers WL may be increased by stacking two or more of the first stacked bodies SK1 each having a predetermined number of layers one on another.

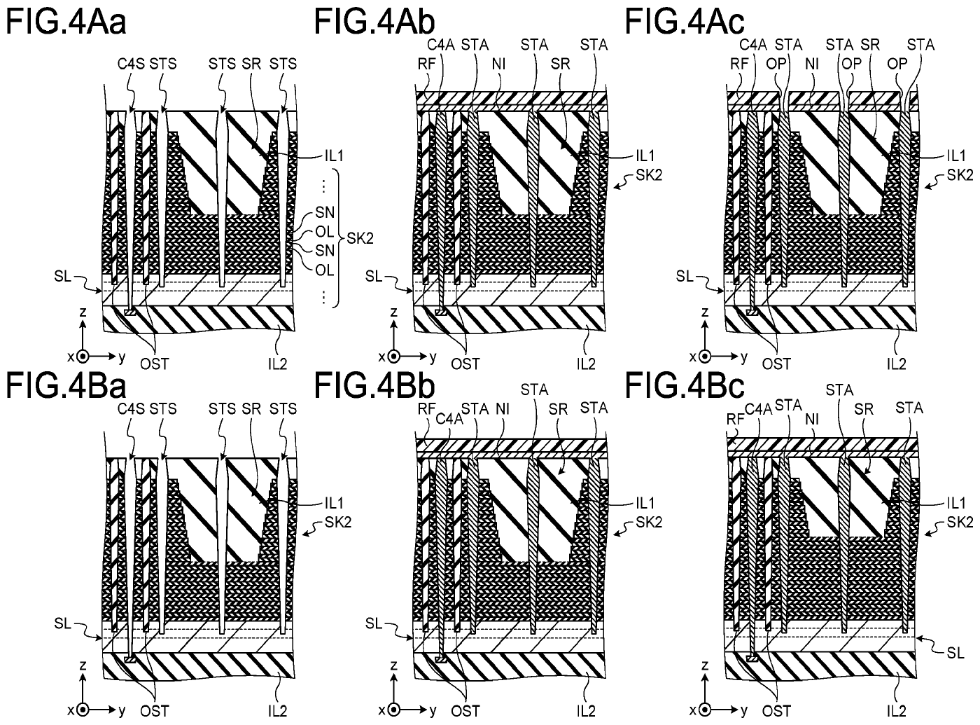

Hereinafter, a method for forming the stair area SA will be described with reference to FIGS. 4Aa to 7Bk. FIGS. 4Aa to 7Ak are partial cross-sectional views taken along line L2-L2 of FIG. 1, and FIGS. 4Ba to 7Bk are partial cross-sectional views taken along line L3-L3 of FIG. 1.

With reference to FIGS. 4Aa and 4Ba, the source line SL is formed on the second interlayer insulating film IL2 of the peripheral circuit unit PER (FIG. 3A), and the second stacked body SK2 is formed thereon. As described above, the second stacked body SK2 includes the insulating layers OL formed of silicon oxide and the sacrificial layers SN formed of silicon nitride, which are alternately stacked. A part of the second stacked body SK2 is processed into the stair portion SR by a series of processes of forming a mask with a photoresist, etching using the mask, slimming the mask, and etching using the slimmed mask. Note that the source line SL here is formed as a temporary source line having a sacrificial layer at the center in the z direction, but for convenience of description, its illustration is omitted in FIGS. 4Aa and 4Ba and the following drawings.

The portion above the stair portion SR is filled with the first interlayer insulating film IL1. Two plate-like bodies OST penetrating the first interlayer insulating film IL1 and the second stacked body SK2 to terminate in the source line SL are formed of silicon oxide. A contact hole C4S penetrating the first interlayer insulating film IL1, the second stacked body SK2, and the source line SL to reach the wiring ML in the second interlayer insulating film IL2 is formed between the two plate-like bodies OST. Note that an opening may be provided in advance in the source line SL at a position where the contact hole C4S is to be formed. The contact hole C4S is provided to form the through contact C4. Furthermore, three slits STS in the drawings, penetrating the first interlayer insulating film IL1 and the second stacked body SK2 to terminate in the source line SL are arranged at substantially equal intervals in the y direction. The stair portion SR is arranged on both sides of the central slit STS among the three slits STS in the drawing. The slits STS are provided to form the plate-like portions ST.

Next, as illustrated in FIGS. 4Ab and 4Bb, a temporary through contact C4A is formed by filling the contact hole C4S with, for example, amorphous silicon, and by similarly filling the three slits STS with, for example, amorphous silicon, temporary plate-like portions STA are formed. A silicon nitride layer NI is deposited on the upper end surfaces thereof, the plate-like bodies OST, and the first interlayer insulating film IL1, and a photoresist film RF is formed thereon.

With reference to FIG. 4Ac, openings OP are formed in the photoresist film RF above the temporary plate-like portions STA, and the silicon nitride layer NI is etched using the photoresist RF having the openings OP as a mask. As a result, the temporary plate-like portions STA are exposed to the bottom surfaces of the openings OP. On the other hand, in FIG. 4Bc, the opening OP is not formed in the photoresist film RF, and therefore the silicon nitride layer NI is not etched.

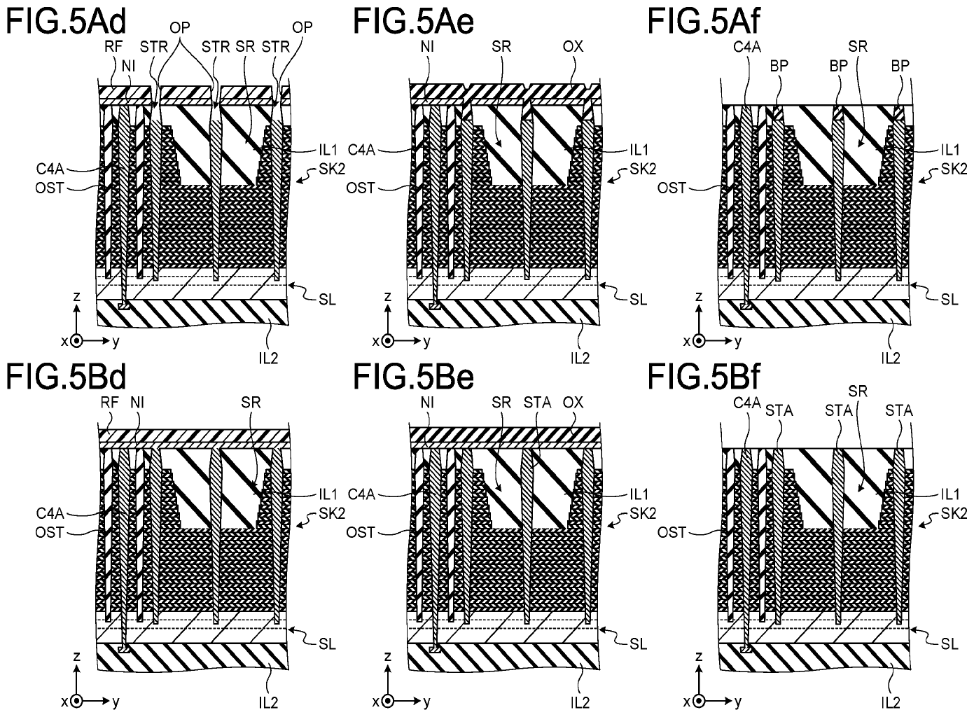

Next, with reference to FIG. 5Ad, the temporary plate-like portions STA exposed to the bottom surface of the photoresist film RF are etched to form concave portions STR. On the other hand, in FIG. 5Bd, no concave portion STR is formed in the temporary plate-like portions STA.

Subsequently, as illustrated in FIG. 5Ae, a silicon oxide layer OX is deposited on the silicon nitride layer NI after the photoresist film RF is removed. At this time, the concave portions STR in the temporary plate-like portions STA are filled with silicon oxide. In FIG. 5Be, the silicon oxide layer OX is only deposited on the silicon nitride layer NI.

Next, as illustrated in FIGS. 5Af and 5Bf, the silicon oxide layer OX is removed by etching, and subsequently the silicon nitride layer NI is removed by etching. At this time, the silicon nitride layer NI serves as an etching stopper layer when the silicon oxide layer OX is etched. In addition, since the silicon nitride layer NI can be etched with a large etching ratio with respect to the first interlayer insulating film IL1 and the like that are base layers thereof, the etching is substantially stopped on the surface of the first interlayer insulating film IL1. Note that the silicon oxide layer OX and the silicon nitride layer NI may be removed by a chemical mechanical polishing (CMP) method instead of etching.

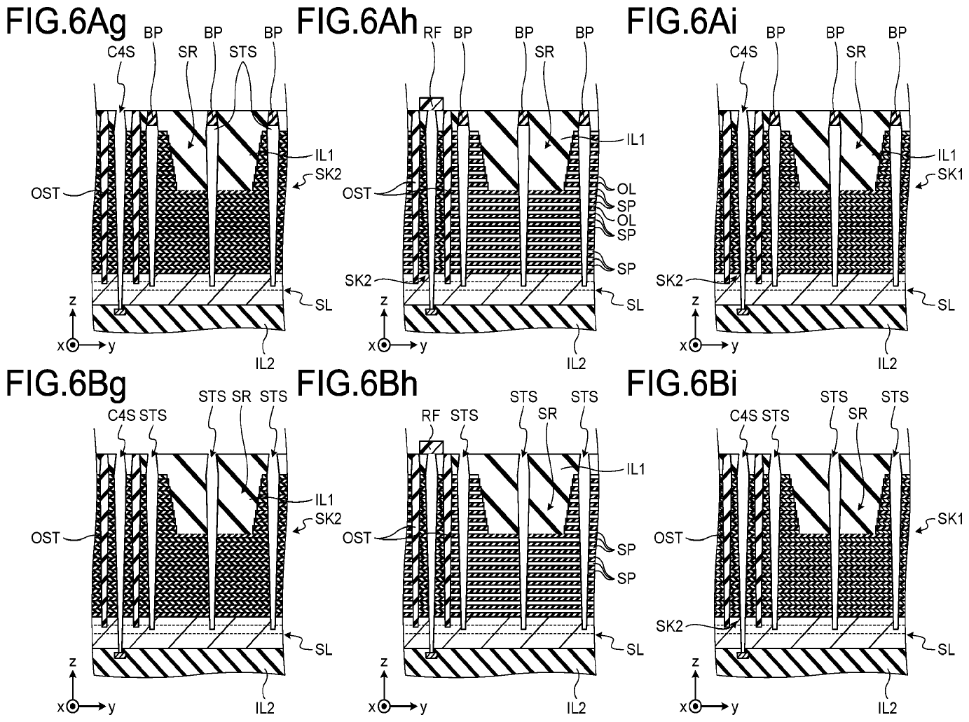

Thereafter, as illustrated in FIGS. 6Ag and 6Bg, the temporary through contact C4A and the temporary plate-like portions STA are removed. Specifically, the temporary through contact C4A and the temporary plate-like portions STA illustrated in, for example, FIG. 5Bf are isotropically etched from the upper surfaces thereof. According to isotropic etching, the temporary plate-like portions STA are etched not only in the depth direction (z direction) but also in the longitudinal direction (x direction). Therefore, as illustrated in FIG. 6Ag, the temporary plate-like portions STA filled with amorphous silicon are removed also under the concave portions STR filled with silicon oxide. As a result, the concave portions STR filled with silicon oxide remain as the bridge portions BP, while the slits STS are formed again under the concave portions STR. In addition, the temporary through contact C4A is also removed, and the contact hole C4S is formed again.

Next, the upper portion of the contact hole C4S is covered with, for example, a photoresist film RF, and then an etching solution is injected into the slits STS to remove the sacrificial layers SN formed of silicon nitride in the second stacked body SK2. Specifically, the sacrificial layers SN exposed to the side surfaces of the slits STS are removed in the x direction and the y direction, whereby spaces SP each occur between the insulating layers OL extending in the x direction and arranged in layers in the z direction, as illustrated in FIGS. 6Ah and 6Bh. Note that the plate-like body OST serves as an etching stopper for the sacrificial layers SN, and the etching, in the y direction, for the sacrificial layers SN ends here. Therefore, the sacrificial layers SN between the two plate-like bodies OST remain without being removed, that is, the second stacked body SK2 remains.

Subsequently, when the spaces SP are filled with a metal, such as tungsten, through the slits STS by, for example, an atomic layer deposition (ALD) method, the conductive layers WL are obtained as illustrated in FIGS. 6Ai and 6Bi. That is, the sacrificial layers SN are replaced with the conductive layers WL, and the second stacked body SK2 becomes the first stacked body SK1. Note that before the spaces SP are filled with a metal such as tungsten, a second block insulating layer may be formed of an insulating material, such as aluminum oxide (Al₂O₃), on the inner surfaces of the spaces SP. Furthermore, a layer of metal, such as tungsten, may be formed inside the second block insulating layer via a barrier metal layer.

Note that as illustrated in FIGS. 6Ah, 6Bh to 6Ai, and 6Bi, the process of replacing the sacrificial layers SN with the word lines WL may be referred to as a replacement process. In this replacement process, the non-illustrated sacrificial layer in the source line SL is also and similarly replaced with a conductive layer.

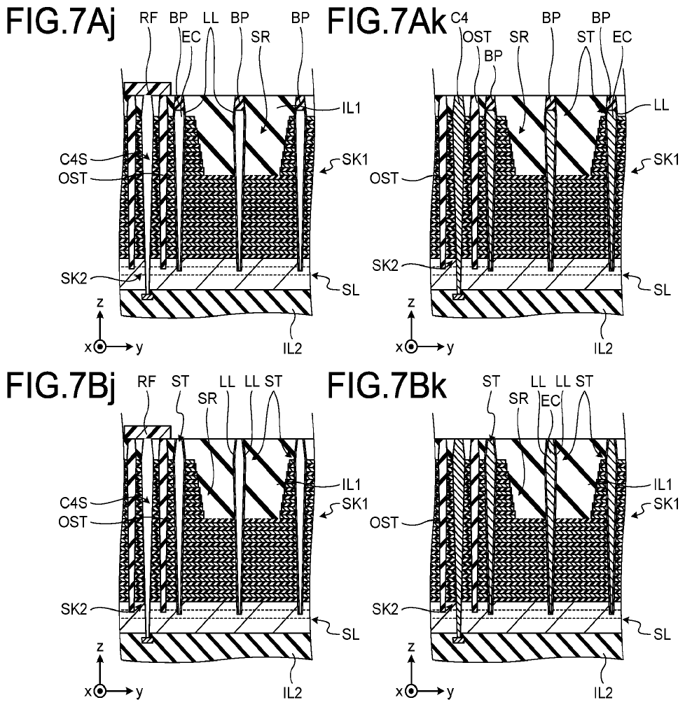

Next, after the upper portion of the contact hole C4S is covered again with, for example, a photoresist film RF, the liner layer LL is formed of, for example, silicon oxide on the inner surfaces of the slits STS, as illustrated in FIGS. 7Aj and 7Bj. At this time, the silicon oxide raw material gas enters through an upper end opening of the slit STS, where the bridge portion BP does not exist, and diffuses also under the bridge portion BP. Therefore, the liner layers LL are also formed under the bridge portions BP.

Thereafter, as illustrated in FIGS. 7Ak and 7Bk, the photoresist film RF on the contact hole C4S is removed, and the insides of the liner layers LL are filled with a metal, such as tungsten, to form the conductive portions EC. The organic metal raw material gas containing a metal, such as tungsten, also diffuses under the bridge portions BP, and therefore the conductive portions EC are also formed under the bridge portions BP. In addition, in the same step, the contact hole C4S is filled with a metal, such as tungsten, to form the through contact C4. Thereafter, when the contact CC penetrating the first interlayer insulating film IL1 to be connected to each of the conductive layers WL as the terrace surface is formed in the stair portion SR, the structure illustrated in FIGS. 3A and 3B is formed.

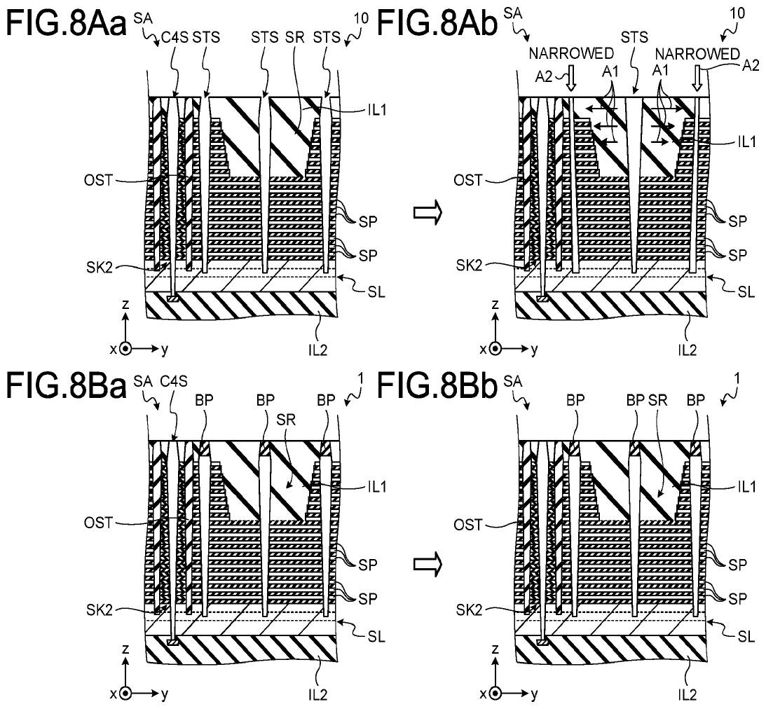

Hereinafter, effects exerted by the bridge portion BP of the semiconductor memory device 1 according to the present embodiment will be described. FIGS. 8Aa and 8Ab are partial cross-sectional views in the yz plane of the stair area SA of a semiconductor memory device 10 not provided with the bridge portion BP. FIGS. 8Ba and 8Bb are partial cross-sectional views in the yz plane of the stair area SA of the semiconductor memory device 1 according to the present embodiment, provided with the bridge portions BP. The semiconductor memory device 10 is different from the semiconductor memory device 1 according to the present embodiment in that it does not have the bridge portion BP, and has substantially the same configurations in other points.

With reference to FIG. 8Aa, the spaces SP each occur between the plurality of insulating layers OL. That is, the sacrificial layers SN of the second stacked body SK2 are removed (see FIGS. 6Ah, 6Bh). Thereafter, for example, Al₂O₃ is deposited on the upper surface of the insulating layer OL under each space SP, which is the bottom surface of the space SP, and the lower surface of the insulating layer OL on each space SP, which is the ceiling surface of the space SP. When a heat treatment is performed, the Al₂O₃ shrinks or the first interlayer insulating film IL1 shrinks, so that a stress as indicated by an arrow A1 may occur. When such a stress occurs, the first interlayer insulating film IL1 bends or tilts in opposite directions on both sides of the central slit STS, as illustrated in FIG. 8Ab. As a result, the upper end of the central slit STS in the drawing is widely opened. On the other hand, the upper ends of the slits STS on the right side and the left side are narrowed, as indicated by an arrow A2. In the subsequent step, the conductive layers WL are formed by filling the spaces SP with a metal, such as tungsten, through the slits STS (see FIGS. 6Ai and 6Bi). Here, if the upper ends of the slits STS on both sides are further narrowed and closed, a raw material gas containing a metal, such as tungsten, cannot be supplied to the spaces SP, so that the conductive layers WL cannot be formed.

On the other hand, in the semiconductor memory device 1 according to the present embodiment, the bridge portion BP is provided in the upper end portion of each slit STS, as illustrated in FIG. 8Ba. The parts of the first interlayer insulating film IL1 arranged on both sides of the slit STS are coupled via the bridge portion BP. Therefore, even if Al₂O₃ or the first interlayer insulating film IL1 shrinks by a heat treatment performed after the Al₂O₃ is deposited on the bottom surfaces and the ceiling surfaces of the spaces SP, the upper end of the central slit STS is hardly widened or the upper ends of the slits STS on both sides thereof are hardly narrowed.

In addition, when the bridge portions BP are intermittently provided at, for example, predetermined intervals (pitch) along the longitudinal direction of the slit STS (x direction), the length in the y direction, which is the width of the upper end opening, of the slit STS hardly changes on both sides of the bridge portion BP in the x direction. Therefore, when the conductive layers WL are formed, the supply of the metal raw material gas to the slits STS is hardly hindered. Furthermore, when the first interlayer insulating film IL1 and the bridge portion BP are both formed of silicon oxide, they can be closely bonded to each other. Therefore, the stress occurring due to the shrinkage of Al₂O₃ or the first interlayer insulating film IL1 can be sufficiently offset. In addition, the bridge portion BP of the central slit STS can offset the tensile stress, and the bridge portions BP of the slits STS on both sides can offset the compressive stress. That is, when the bridge portions BP are arranged to be aligned in the y direction, as illustrated in FIG. 1, the stress occurring due to the shrinkage of Al₂O₃ or the first interlayer insulating film IL1 can be more sufficiently offset.

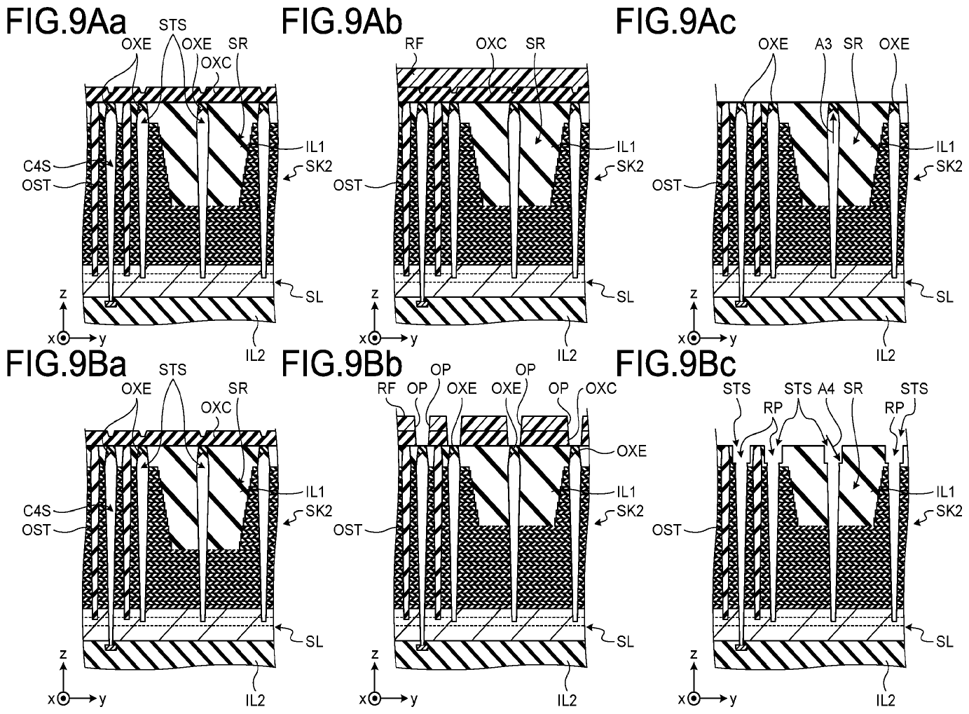

Note that the bridge portion BP can also be formed by, for example, a forming method according to a comparative example as described below. FIGS. 9Aa to 9Bc are partial cross-sectional views for explaining a method of forming a stair area of a semiconductor memory device according to a comparative example; FIGS. 9Aa to 9Ac are partial cross-sectional views at a position where a bridge portion is formed, while FIGS. 9Ba to 9Bc are partial cross-sectional views at a position where no bridge portion is formed.

With reference to FIGS. 9Aa and 9Ba, a contact hole C4S for a through contact C4 and slits STS for plate-like portions ST are formed to penetrate a first interlayer insulating film IL1 and a second stacked body SK2. In addition, a silicon oxide film OXC is deposited on the first interlayer insulating film IL1. Here, the silicon oxide film OXC also enters the upper end portions of the contact hole C4S and the slits STS, so that filled portions OXE are formed therein. Next, as illustrated in FIGS. 9Ab and 9Bb, a photoresist film RF is formed on the silicon oxide film OXC. In FIG. 9Ab, no opening is formed in the photoresist film RF above the filled portions OXE. On the other hand, in FIG. 9Bb, openings OP are formed in the photoresist film RF. When etching is performed using the photoresist film RF, the silicon oxide films OXC exposed to the openings OP are etched, and the filled portions OXE under the silicon oxide films OXC are also removed by the etching.

Thereafter, when the silicon oxide film OXC remaining on the first interlayer insulating film IL1 and the photoresist film RF are removed, the filled portions OXE remain as bridge portions, and under the filled portions OXE, the slits STS extend to a source line SL, in FIG. 9Ac. On the other hand, in FIG. 9Bc, no filled portion OXE exists, and the slits STS are opened. Here, with reference to FIG. 9Ac, the lower surface of the filled portion OXE as the bridge portion is recessed at an acute angle at the central portion, as indicated by an arrow A3. This is considered to be caused because silicon oxide was deposited along the side surface of the slit STS when the silicon oxide film OXC was formed. When the filled portion OXE as a bridge portion has a portion recessed at such an acute angle, there is a risk that a crack may occur due to the stress occurring, for example, when a heat treatment is performed. In addition, in such a portion recessed at an acute angle, a metal such as tungsten, which is deposited when the sacrificial layers SN are later replaced with the conductive layers WL, may remain. After the conductive layers WL are formed, the metal deposited on the inner side surface of the slit STS is removed, but in the portion recessed at an acute angle, the metal cannot be removed. In this case, the metal is confined in the portion recessed at an acute angle by the liner layer LL formed thereafter.

In addition, with reference to FIG. 9Bc, concave portions RP are formed in the upper end portions of the slits STS when the filled portions OXE are etched, so that steps each occur between the slit STS and the concave portion RP, as indicated by an arrow A4. Such a step is considered to be caused because the parts of the first interlayer insulating film IL1 arranged on both sides of the filled portion OXE are also etched when the filled portion OXE is etched. The shape of the concave portion RP having such a step remains even after an insulating layer is formed on the inner side surface of the slit STS and a metal, such as tungsten, is filled inside the insulating layer.

Contrary to the above, in the method for forming the stair area SA of the semiconductor memory device 1 according to the present embodiment described with reference to FIGS. 4Aa to 7Bk, the temporary plate-like portions STA are formed by filling the slits STS with, for example, amorphous silicon (FIG. 4Ab), and the concave portions STR are formed by etching the upper end portions of the temporary plate-like portions STA (FIG. 5Ad). Since the upper surface of the concave portion STR formed by etching is substantially flat and the bridge portion BP is formed by filling the concave portion STR with silicon oxide, the lower surface of the bridge portion BP is also substantially flat. That is, a recessed portion as indicated by the arrow A3 in FIG. 9Ac does not occur. In addition, the concave portion STR is not formed at the position where the bridge portion BP is not formed, and unlike FIGS. 9Bb and 9Bc, the filled portion OXE once formed in the upper end portion of the slit STS is not removed. Therefore, the step indicated by the arrow A4 in FIG. 9Bc does not occur.

(First Modification)

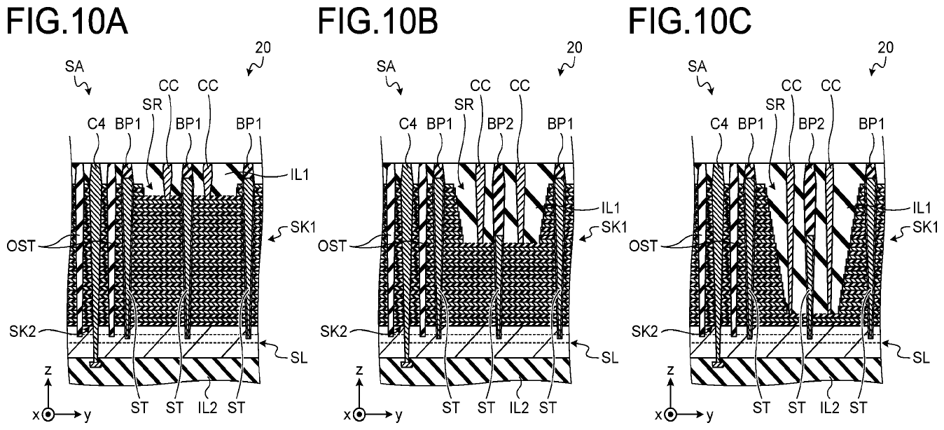

With reference to FIGS. 10A to 10C, a semiconductor memory device 20 according to a first modification of the first embodiment will be described. FIGS. 10A to 10C are partial cross-sectional views of the stair area SA at three positions where the heights of the terrace surfaces of a stair portion SR in the z direction are different. The semiconductor memory device 20 according to the first modification of the first embodiment has the same stair portion SR as the semiconductor memory device 1 according to the first embodiment described above. In the stair portion SR, the steps STP descend as moving away from the cell array area CA, as illustrated in FIG. 2. FIGS. 10A, 10B, and 10C are partial cross-sectional views of a upper layer portion, a middle layer portion, and a lower layer portion of the stair portion SR, respectively. As can be seen from these views, in the upper layer portion of the stair portion SR, that is, in a portion where the terrace surface is high, bridge portions BP1 are provided in three plate-like portions ST. That is, in the upper layer portion, even the central plate-like portion ST is provided with the bridge portion BP1 having a depth, that is, a length in the z direction, that is the same as those of the plate-like portions ST on both sides. On the other hand, in the middle layer portion and the lower layer portion of the stair portion SR, the central plate-like portion ST is provided with a bridge portion BP2 deeper than the bridge portion BP1, and the plate-like portions ST on both sides are each provided with the bridge portion BP1. Note that the semiconductor memory device 20 according to the first modification of the first embodiment has substantially the same configurations as the semiconductor memory device 1 according to the first embodiment, except that the depth of the bridge portion BP in the central plate-like portion ST is different. That is, the bridge portions BP1 provided in the plate-like portions ST on both sides are all aligned in the y direction with the bridge portion BP1 or BP2 provided in the central plate-like portion ST.

In the middle layer portion and the lower layer portion of the stair portion SR, the first interlayer insulating film IL1 is thicker than in the upper layer portion, so that the ratio of silicon oxide in the constituent ratio of materials increases in the area between the two adjacent plate-like portions ST. As a result, it is considered that the stress acting between the first stacked body SK1 and the first interlayer insulating film IL1 also increases. As described above, the first stacked body SK1 is formed by replacing the sacrificial layers SN of the second stacked body SK2 with the conductive layers WL (see FIG. 6Ai, FIG. 6Bi), and at that time Al₂O₃ is deposited in the spaces SP formed by removing the sacrificial layers SN. Thereafter, a heat treatment step may be performed. At this time, the stress occurring due to the shrinkage of Al₂O₃ or the first interlayer insulating film IL1 can be larger as the first interlayer insulating film IL1 is thicker. Therefore, in the middle layer portion and the lower layer portion of the stair portion SR, the deep bridge portion BP2 is provided in the central slit STS to be the plate-like portion ST, as illustrated in FIGS. 10B and 10C, so that the stress can be sufficiently offset, and the first interlayer insulating film IL1, the first stacked body SK1, and eventually the slit STS can be prevented from deforming. Therefore, even in the middle layer portion and the lower layer portion of the stair portion SR, the openings at the upper ends of the two slits STS on both sides of the central slit STS, that is, those of the slits STS on both sides along the x direction of the bridge portion BP1 are hardly narrowed. Therefore, the formation of the conductive layers WL can be prevented from being hindered.

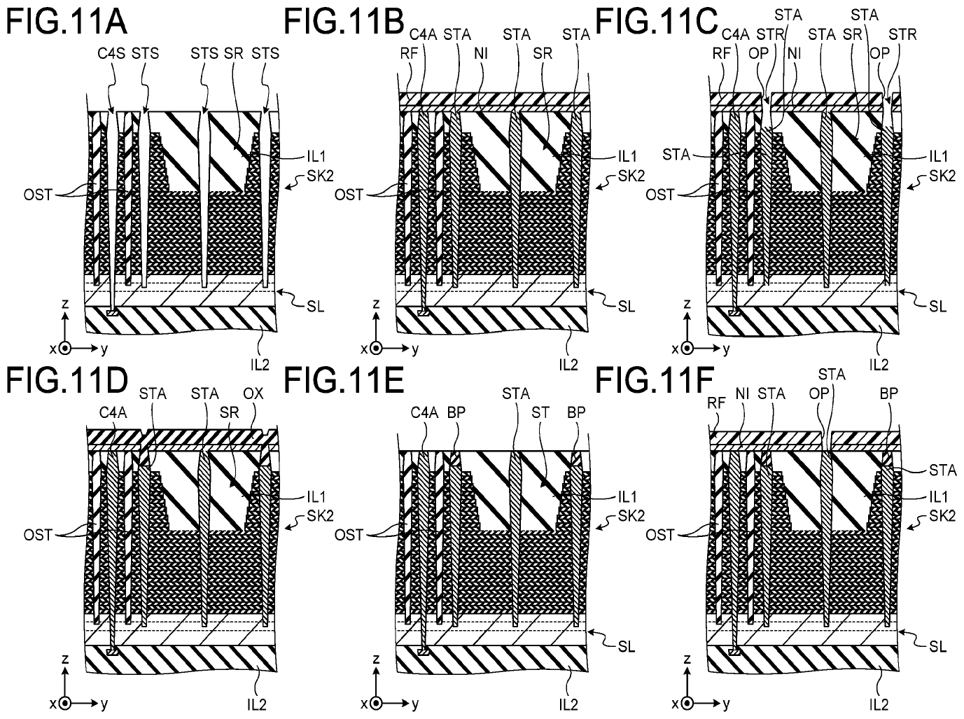

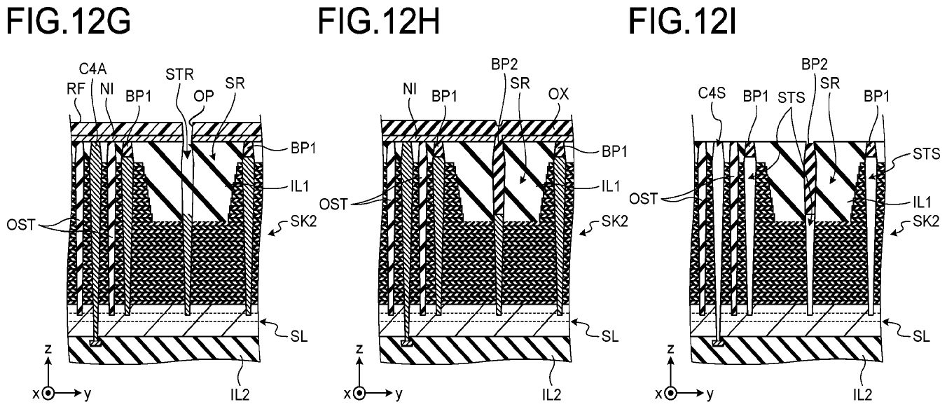

Next, with reference to FIGS. 11A to 12I, a method for forming the stair area SA including the deep bridge portion BP2 illustrated in FIGS. 10B and 10C will be described. FIGS. 11A to 12I are partial cross-sectional views for explaining a method for forming the stair area SA of the semiconductor memory device 20 according to the first modification of the first embodiment, and in detail those are partial cross-sectional views at positions where the bridge portions BP1 and BP2 are provided in the middle layer portion of the stair portion SR in FIG. 10B.

With reference to FIG. 11A, the contact hole C4S penetrating the first interlayer insulating film IL1 and the second stacked body SK2 and three slits STS are formed. As illustrated in FIG. 11B, these contact hole C4S and slits STS are filled with, for example, amorphous silicon, so that the temporary through contact C4A and three temporary plate-like portions STA are formed. The silicon nitride layer NI and the photoresist film RF are formed on the upper surfaces thereof and on the first interlayer insulating film IL1.

Next, as illustrated in FIG. 11C, the openings OP are formed in the photoresist film RF above the temporary plate-like portions STA on both sides among the three temporary plate-like portions STA. The opening OP is not formed above the central temporary plate-like portion STA. Next, the silicon nitride layer NI exposed to the openings OP and the upper end portions of the temporary plate-like portions STA thereunder are removed by etching using the photoresist film RF as a mask. As a result, the concave portions STR are formed in the upper end portions of the temporary plate-like portions STA on both sides.

Next, after the photoresist film RF is removed, the silicon oxide film OX is formed on the silicon nitride layer NI, as illustrated in FIG. 11D. At this time, the concave portions STR are also filled with silicon oxide. Thereafter, the silicon oxide film OX and the silicon nitride layer NI are sequentially removed by etching, as illustrated in FIG. 11E, whereby the bridge portions BP1 are formed in the upper end portions of the two temporary plate-like portions STA. Subsequently, the silicon nitride layer NI and the photoresist film RF are formed again on the first interlayer insulating film IL1 and the like, as illustrated in FIG. 11F. In the photoresist film RF, the opening OP is formed above the central temporary plate-like portion STA, so that the silicon nitride layer NI exposed to the opening OP and the upper end portion side of the temporary plate-like portion STA thereunder are removed by etching. In this etching, the etching time can be made longer than the etching described with reference to FIG. 11C, and as a result, the deep concave portion STR is formed on the upper end portion side of the central temporary plate-like portion STA, as illustrated in FIG. 12G.

Next, after the photoresist film RF is removed, the silicon oxide film OX is formed on the silicon nitride layer NI. At this time, the deep concave portion STR is also filled with silicon oxide, as illustrated in FIG. 12H. Thereafter, when the silicon oxide film OX and the silicon nitride layer NI are sequentially removed by etching, the bridge portion BP2 made of silicon oxide filled in the deep concave portion STR is obtained. Furthermore, when the temporary plate-like portions STA and the temporary through contact C4A are removed, the contact hole C4S, the central slit STS having the bridge portion BP2 on the upper end portion side, and the slits STS on both sides each having the bridge portion BP1 in the upper end portion are formed, as illustrated in FIG. 12I. As described above, the slits STS are used to replace the sacrificial layers SN of the second stacked body SK2 with the conductive layers WL. That is, the same steps as the steps described with reference to FIGS. 6Ah to 7Ak are performed to obtain the structure illustrated in FIG. 10B.

Also in the above forming method, the temporary plate-like portions STA are formed by filling the slits STS with, for example, amorphous silicon (FIG. 11B), and the concave portions STR are formed by etching the upper end portions of the temporary plate-like portions STA (FIGS. 11C and 12G). Since the upper surfaces of the concave portions STR formed by etching are substantially flat and the bridge portions BP1 and BP2 are formed by filling the concave portions STR with silicon oxide, the lower surfaces of the bridge portions BP1 and BP2 are also substantially flat. That is, a recessed portion as indicated by the arrow A3 in FIG. 9Ac does not occur also in the semiconductor memory device 20 according to the first modification.

Note that in the above description, the depth of the bridge portion BP1 in the upper layer portion of the stair portion SR is different from the depths of the bridge portions BP2 in the middle layer portion and the lower layer portion, but the depth of the bridge portion BP may be different depending on the height of the terrace surface of the stair portion SR. For example, the bridge portion BP in each of the upper layer portion, the middle layer portion, and the lower layer portion may be formed to have a different depth from those of the other two. That is, the bridge portions BP in the upper layer portion, the middle layer portion, and the lower layer portion may be deeper in this order. In addition, the bridge portions BP each having one of four or more depths, not limited to the three depths, may be provided depending on the heights of the terrace surfaces of the stair portion SR. In addition, even when the bridge portions BP having a single depth are formed, or even when the bridge portions BP are formed to have different depths according to the upper layer portion, the middle layer portion, and the lower layer portion, it is desirable that the bridge portions BP are shallower than the heights of the terrace surfaces. In other words, it is desirable that the lower surfaces of the bridge portions BP, BP1, and BP2 are higher than the corresponding terrace surfaces. As a result, when the sacrificial layers SN of the second stacked body SK2 are removed (see FIGS. 6Ah and 6Bh), the sacrificial layers SN are exposed to the side surfaces of the slits STS under the bridge portions BP, BP1, and BP2, so that the sacrificial layers SN can be easily removed via the slits STS.

(Second Modification)

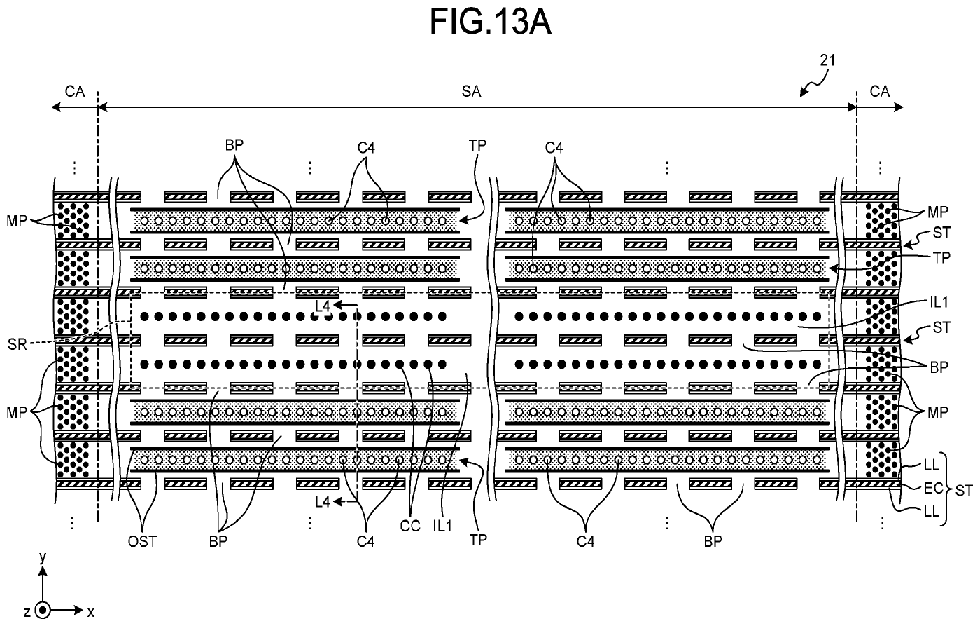

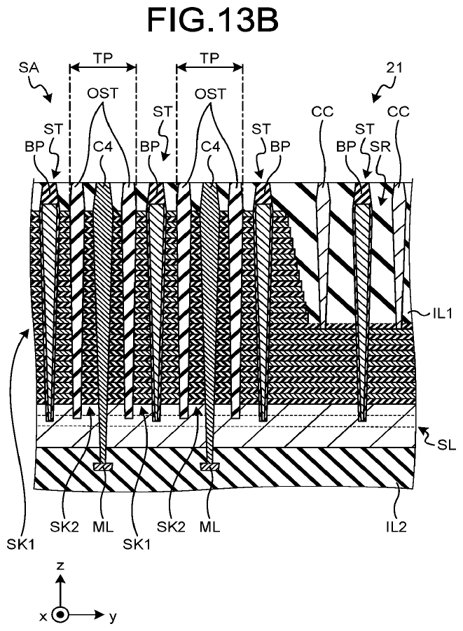

Next, with reference to FIGS. 13A and 13B, a semiconductor memory device 21 according to a second modification of the first embodiment will be described. FIG. 13A is a partial cross-sectional view of the semiconductor memory device 21 according to the second modification of the first embodiment, and corresponds to the partial top view of the semiconductor memory device 1 illustrated in FIG. 1. FIG. 13B is a cross-sectional view taken along line L4-L4 of FIG. 13A.

In the semiconductor memory device 21 according to the second modification, the bridge portions BP are also intermittently provided in the plate-like portion ST between the through connecting portions TP of the stair area SA, as illustrated in FIG. 13A. In the present modification, the length in the x direction of the bridge portion BP and the interval between the adjacent bridge portions BP are the same as those of the bridge portions BP provided in the other plate-like portions ST. Therefore, in the semiconductor memory device 21, the bridge portions BP formed in the plate-like portions ST of the stair area SA are aligned in the y direction.

In addition, as illustrated in FIG. 13B, the bridge portion BP provided in the upper end portion of the plate-like portion ST between the through connecting portions TP has the same depth as the bridge portions BP in the plate-like portions ST on both sides of the plate-like portion ST. In addition, the interlayer insulating film IL1 is also formed on the first stacked body SK1 between the through connecting portions TP, and the interlayer insulating film IL1 in this portion are coupled via the bridge portion BP.

Note that the bridge portion BP in the plate-like portion ST between the through connecting portions TP can be formed by changing the method for forming the stair area SA of the semiconductor memory device 1 according to the embodiment described with reference to FIGS. 4Aa to 7Bk. That is, the slit for the plate-like portion ST between the through connecting portions TP may also be filled with, for example, amorphous silicon to form the temporary plate-like portion STA in FIG. 4Ab, and then the opening OP may be formed in the photoresist film RF above the temporary plate-like portion STA, as illustrated in FIG. 4Ac. As a result, the concave portion STR, similar to the concave portion STR illustrated in FIG. 5Ad, is also formed in the upper end portion of the plate-like portion STA, and the bridge portion BP can be formed by filling the concave portion STR with silicon oxide.

The stress occurring in Al₂O₃ or the interlayer insulating film IL1 described above can also affect the through connecting portion TP. Although not illustrated in FIG. 13B, the stair portion SR is also formed on the left side of FIG. 13B, so that the two through connecting portions TP in the drawing may be subjected to stress that brings the upper ends close to each other. In the semiconductor memory device 21 according to the second modification, the bridge portion BP is also provided in the slit STS for forming the plate-like portion ST between the through connecting portions TP, so that the through connecting portion TP can be prevented from tilting. In addition, as described above, the bridge portion BP in the plate-like portion ST between the through connecting portions TP can also be formed in the same step as the bridge portions BP in the other plate-like portions ST, so that the lower surface is substantially flat. That is, a recessed portion as indicated by the arrow A3 in FIG. 9Ac does not occur also in the semiconductor memory device 21 according to the second modification.

### Second Embodiment

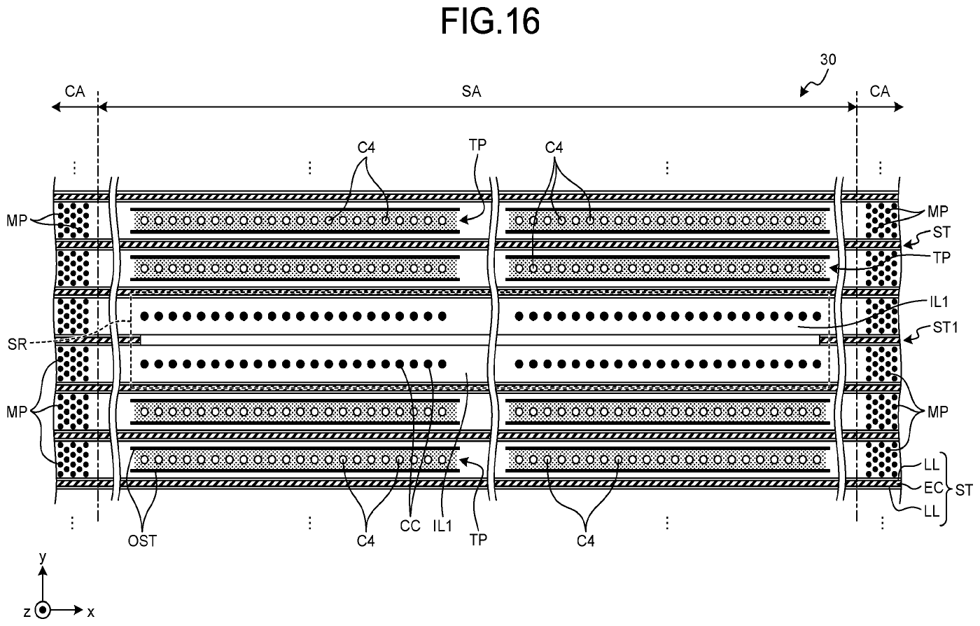

Next, a semiconductor memory device according to a second embodiment will be described. FIG. 16 illustrates a partial top view of the semiconductor memory device according to the second embodiment. A semiconductor memory device 30 according to the second embodiment is different from the semiconductor memory device 1 according to the first embodiment in that the bridge portions BP are not provided in a plate-like portion ST and the conductive portion EC is not provided in a part thereof. The other configurations are substantially the same. That is, each plate-like portion ST in a stair portion SR of the semiconductor memory device 30 has the structure illustrated in FIG. 3B over the entire longitudinal direction of the plate-like portion ST (x direction), except that the conductive portion EC is not provided in a central plate-like portion ST1, on both sides of which the stair portion SR is arranged. The description of the structure is omitted here.

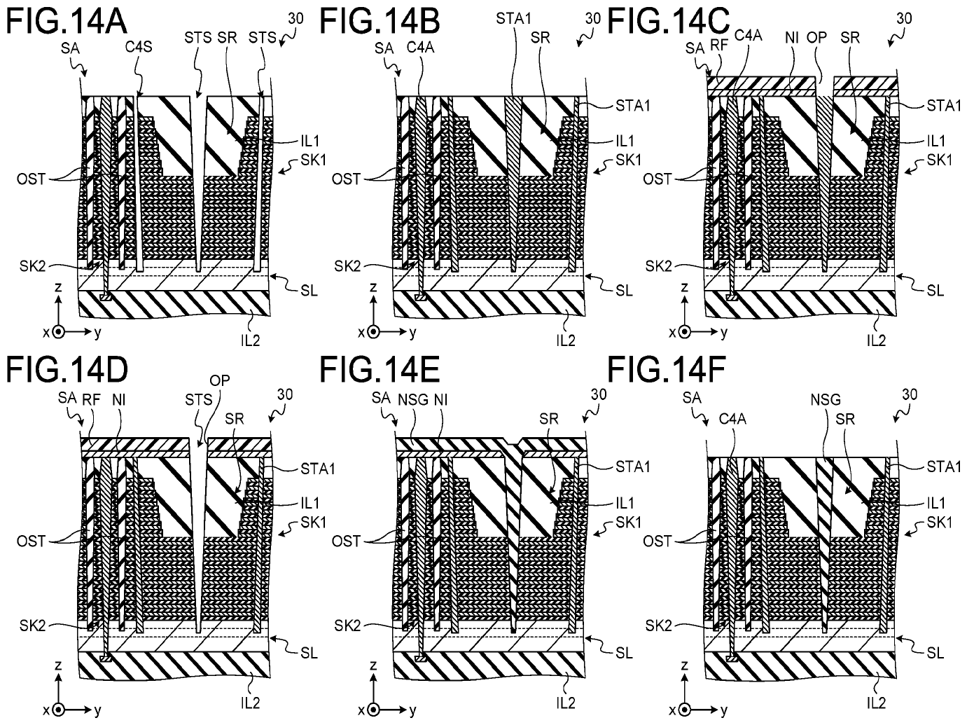

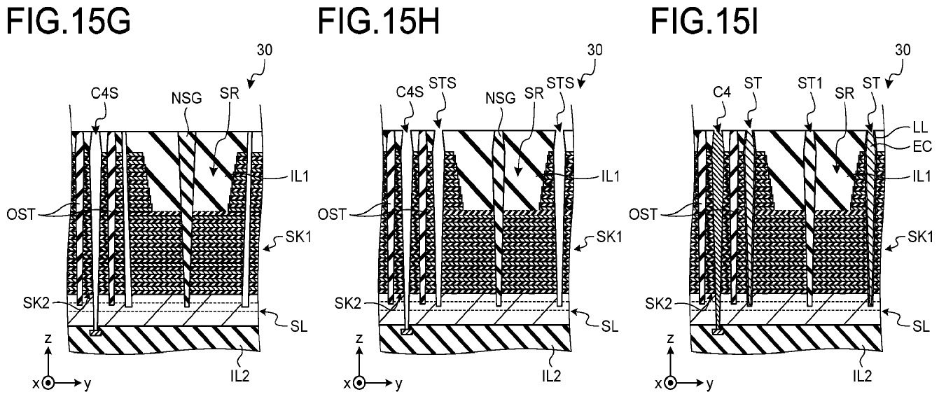

With reference to FIGS. 14A to 15I, a method for forming a stair area SA of the semiconductor memory device 30 according to the second embodiment will be described. FIGS. 14A to 15I are partial cross-sectional views for explaining the method for forming the stair area SA of the semiconductor memory device 30. As illustrated in FIG. 14A, the opening at the upper end of a slit STS for the central plate-like portion, on both sides of which the stair portion SR is arranged, is widened, and the openings at the upper ends of slits STS on both sides thereof are narrowed to the extent of not being closed. And, sacrificial layers SN of a second stacked body SK2 are replaced with conductive layers WL through these slits STS (see (FIGS. 6Ai and 6Bi)).

Next, as illustrated in FIG. 14B, a temporary plate-like portion STA1 is obtained by filling the slit STS with, for example, amorphous silicon. Thereafter, as illustrated in FIG. 14C, a silicon nitride layer NI is formed on a first interlayer insulating film IL1 and the like, and a photoresist film RF is formed on the silicon nitride layer NI. In the photoresist film RF, an opening OP is formed above the central slit STS, the silicon nitride layer NI exposed to the opening OP and the temporary plate-like portion STA1 thereunder are removed, and the central slit STS is obtained again (FIG. 14D).

Next, as illustrated in FIG. 14E, the photoresist film RF is removed, and a silicon oxide layer NSG is formed on the silicon nitride layer NI. At this time, the central slit STS is filled with silicon oxide, and the silicon oxide layer NSG is also formed here. Here, the silicon oxide layer NSG may be formed by a chemical vapor deposition (CVD) method using, for example, ozone (O₃) and tetraethoxysilane (TEOS) as raw material gases. According to this method, the silicon oxide layer NSG that is relatively sparse is formed at a relatively low temperature. In addition, according to this CVD method, the central slit STS can be easily filled with the silicon oxide layer NSG. Thereafter, as illustrated in FIG. 14F, the silicon oxide layer NSG and the silicon nitride layer NI on the first interlayer insulating film IL1 are removed.

Next, as illustrated in FIG. 15G, a temporary through contact C4A is removed, and a contact hole C4S is formed again. In the same step, the temporary plate-like portions STAT remaining are also removed, and the slits STS on both sides are formed again. Thereafter, a heat treatment is performed. By this heat treatment, the silicon oxide layer NSG in the central slit STS is densified and shrinks. As a result, the opening at the upper end of the slit STS is narrowed, and the openings at the upper ends of the slits STS on both sides thereof are widened, as illustrated in FIG. 15H.

Thereafter, the liner layer LL is formed on the inner side surfaces of the two slits STS with the openings at the upper ends opened, and a metal, such as tungsten, is filled inside the liner layer LL to form a conductive portion EC, so that two plate-like portions ST as illustrated in FIG. 15I are obtained. That is, in the present embodiment, while the central plate-like portion ST1 in the stair area SA is formed of silicon oxide obtained by densifying the silicon oxide layer NSG, the plate-like portions ST on both sides thereof have the liner layer LL and the conductive portion EC inside the liner layer LL, and function as a source contact. Note that in the same step as the formation of the conductive portion EC, a metal is also filled in the contact hole C4S to form a through contact C4. In addition, the central plate-like portion ST1 extends, in the x direction, in the stair area SA, and may be connected to the plate-like portion ST having the conductive portion EC and extending, in the x direction, in a cell array area CA, near the boundary between the stair area SA and the cell array area CA.

As can be seen by comparing FIG. 14A and FIG. 15H, the widths of the three slits STS are substantially equal in FIG. 15H, so that the three plate-like portions ST, ST1, and ST each also have a substantially equal width.

From the above, the semiconductor memory device 30 according to the second embodiment illustrated in the top view of FIG. 16 can be obtained. As illustrated in FIG. 16, the plate-like portion ST1 including, in the core portion, the silicon oxide layer NSG, as an insulating member, that extends in the x direction at a position overlapping the stair portion SR in the z direction and that is densified; the plate-like portion ST including, in the core portion, the conductive portion EC, as a conductive member, that extends in the x direction, and extending along the side surface of the stair portion SR; and the plate-like portion ST including, in the core portion, the conductive portion EC that extends in the x direction, and being arranged between the through connecting portions TP, are all arranged at substantially equal intervals in the y direction.

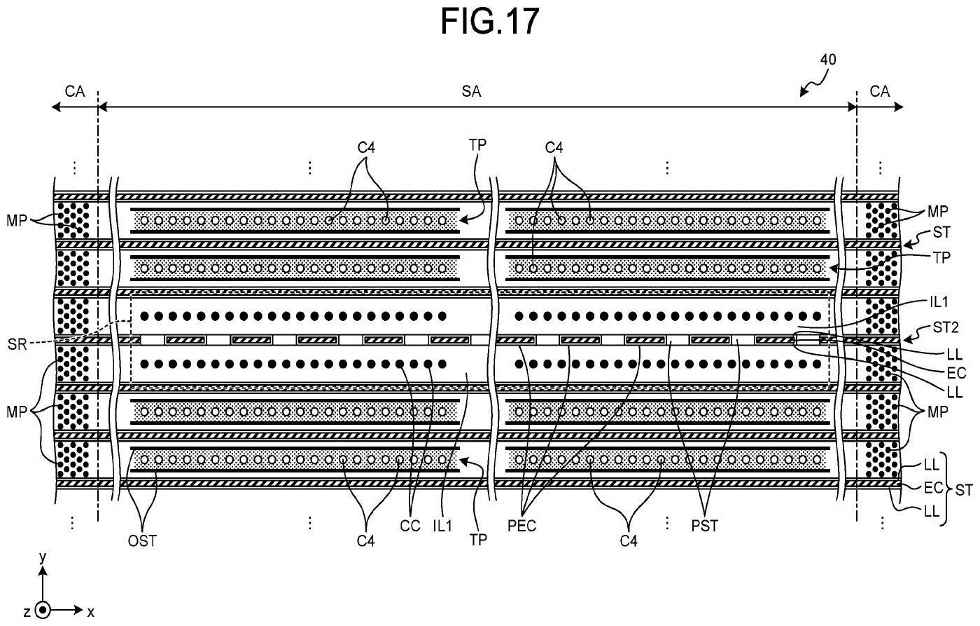

Note that in the above description, the central plate-like portion ST1 is uniformly formed of silicon oxide in the stair area SA, but may be intermittently formed of silicon oxide in the x direction in plan view. FIG. 17 is a partial top view of a semiconductor memory device according to such a modification of the second embodiment. As illustrated in FIG. 17, a semiconductor memory device 40 according to the modification of the second embodiment is different from the semiconductor memory device 30 according to the second embodiment in that a plate-like portion ST2 extending in the x direction at a position overlapping the stair portion SR in the z direction includes densified silicon oxide intermittently, not continuously. That is, the plate-like portion ST2 extends in the x direction at a position overlapping the stair portion SR in the z direction, and includes partial plate-like portions PST and partial conductive portions PEC that are arranged alternately with each other. The partial plate-like portion PST includes, for example, silicon oxide, as an insulating member, that is obtained by intermittently filling a slit, extending in the x direction across the center of the stair portion SR, with a relatively sparse silicon oxide layer and then densifying the silicon oxide layer by a heat treatment. The conductive portion PEC extends in the z direction between the partial plate-like portions PST intermittently arranged in the x direction to reach a source line SL, and has the liner layer LL and the conductive portion EC, similarly to the plate-like portion ST. The conductive portion EC of the partial conductive portion PEC is in contact with the liner layer LL on both sides in the x direction and the y direction, and is connected to the partial plate-like portion PST via the liner layer LL on both sides in the x direction. As a result, the conductive portion EC can be electrically connected to the source line SL while being insulated from the conductive layers WL. That is, in the central plate-like portion ST2, the conductive portions EC of the partial conductive portions PEC intermittently provided along the x direction can function as a source contact, similarly to the plate-like conductive portions EC in the plate-like portions ST on both sides.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first stacked body in which a plurality of first conductive layers and a plurality of first insulating layers are alternately stacked one by one, the first stacked body including a stair portion processed into a stair shape extending in a first direction intersecting with a stacking direction of the first stacked body such that the plurality of first conductive layers forms a plurality of terrace surfaces;
an insulating film covering an upper portion of the first stacked body including the stair portion; and
a first plate-like portion that extends in the first direction in the stair portion and penetrates the first stacked body in the stacking direction, the first plate-like portion including a plurality of bridge portions that are arranged locally on an upper end portion side and intermittently in the first direction to couple parts of the insulating film arranged on both sides of the first plate-like portion to each other.

2. The semiconductor memory device according to claim 1, wherein
each of the plurality of bridge portions in the first plate-like portion has a substantially flat lower surface.

3. The semiconductor memory device according to claim 1, wherein
the first plate-like portion includes a plurality of first plate-like portions, and
the plurality of first plate-like portions includes:
a first plate-like portion extending in the first direction at a position overlapping the stair portion in the stacking direction; and
a first plate-like portion extending in the first direction along one side surface of the stair portion.

4. The semiconductor memory device according to claim 3, wherein
each of the plurality of bridge portions in the first plate-like portion overlapping the stair portion in the stacking direction and each of the plurality of bridge portions in the first plate-like portion extending along the one side surface of the stair portion each have a lower end portion at a position higher than an upper surface of the first stacked body.

5. The semiconductor memory device according to claim 3, wherein
the plurality of bridge portions in the first plate-like portion overlapping the stair portion in the stacking direction and the plurality of bridge portions in the first plate-like portion extending along the one side surface of the stair portion are arranged at positions corresponding to each other in a second direction intersecting with the first direction and the stacking direction.

6. The semiconductor memory device according to claim 5, wherein
first one bridge portion among the plurality of bridge portions in the first plate-like portion overlapping the stair portion in the stacking direction and second one bridge portion among the plurality of bridge portions arranged at a position corresponding to the first one bridge portion in the second direction and in the first plate-like portion extending along the one side surface of the stair portion have different lengths in the stacking direction.

7. The semiconductor memory device according to claim 1, wherein
the first plate-like portion includes a plurality of first plate-like portions,
the plurality of first plate-like portions includes at least a first plate-like portion extending in the first direction at a position overlapping the stair portion in the stacking direction, and
the plurality of bridge portions in the first plate-like portion overlapping the stair portion in the stacking direction includes a first bridge portion having a first length as a length in the stacking direction, and a second bridge portion having a second length as a length in the stacking direction that is longer than the first length.

8. The semiconductor memory device according to claim 7, wherein
the first bridge portion is arranged above a first terrace surface among the plurality of terrace surfaces, and
the second bridge portion is arranged above a second terrace surface among the plurality of terrace surfaces, the second terrace surface being a lower layer than a layer of the first terrace surface.

9. The semiconductor memory device according to claim 7, wherein
the first bridge portion has a lower end portion at a position higher than an upper surface of the first stacked body, and
the second bridge portion has a lower end portion at a position lower than the upper surface of the first stacked body.

10. The semiconductor memory device according to claim 7, wherein
the plurality of first plate-like portions further includes at least a first plate-like portion extending in the first direction along one side surface of the stair portion, and
the plurality of bridge portions in the first plate-like portion extending along the one side surface of the stair portion includes the first bridge portion and do not include the second bridge portion.

11. The semiconductor memory device according to claim 10, wherein
the plurality of bridge portions in the first plate-like portion overlapping the stair portion in the stacking direction and the plurality of bridge portions in the first plate-like portion extending along the one side surface of the stair portion are arranged at positions corresponding to each other in a second direction intersecting with the first direction and the stacking direction.

12. The semiconductor memory device according to claim 1, further comprising:
a memory pillar penetrating the first stacked body in the stacking direction, in portions of which facing the plurality of first conductive layers memory cells being formed;
a circuit unit that is provided below the first stacked body and controls the memory cells via the plurality of first conductive layers;
a plurality of second stacked bodies provided side by side, in a second direction intersecting with the first direction and the stacking direction, in the first stacked body, each of the second stacked bodies extending in the first direction, and the plurality of first insulating layers and a plurality of second insulating layers being alternately stacked one by one in the stacking direction in each of the second stacked bodies;
a plurality of contacts penetrating the plurality of second stacked bodies respectively in the stacking direction to be electrically connected to the circuit unit; and
a second plate-like portion that is arranged between the plurality of second stacked bodies aligned in the second direction, extends in the first direction, and penetrates the first stacked body in the stacking direction, the second plate-like portion including a plurality of bridge portions that are arranged locally on an upper end portion side and intermittently in the first direction to couple parts of the insulating film arranged on both sides of the second plate-like portion to each other.

13. The semiconductor memory device according to claim 12, wherein
each of the plurality of bridge portions in the second plate-like portion has a lower end portion at a position higher than an upper surface of the first stacked body.

14. The semiconductor memory device according to claim 12, wherein
each of the plurality of bridge portions in the second plate-like portion has a substantially flat lower surface.

15. The semiconductor memory device according to claim 12, wherein
the plurality of bridge portions in the first plate-like portion and the plurality of bridge portions in the second plate-like portion are arranged at positions corresponding to each other in the second direction.

16. The semiconductor memory device according to claim 1, wherein
a portion of the first plate-like portion other than the plurality of bridge portions is filled with a conductive portion having a liner layer on a side wall facing a second direction intersecting with the first direction and the stacking direction.

17. A semiconductor memory device comprising:
a stacked body in which a plurality of first conductive layers and a plurality of first insulating layers are alternately stacked one by one, the stacked body including a stair portion processed into a stair shape extending in a first direction intersecting with a stacking direction of the stacked body such that the plurality of first conductive layers forms a plurality of terrace surfaces; and
a plurality of first plate-like portions that extend in the first direction and penetrate the stacked body in the stacking direction, wherein
the plurality of first plate-like portions includes
a first one of plate-like portion among the plurality of first plate-like portions, that is arranged at a position overlapping the stair portion in the stacking direction and includes an insulating member continuously or intermittently extending in the first direction, and
a second one of plate-like portion among the plurality of first plate-like portions, that is arranged on an opposite side of the first one of plate-like portion with respect to the stair portion and includes a conductive member extending, in the first direction, with a first length, and
the first one of plate-like portion does not include a conductive portion extending, in the first direction, with a length greater than or equal to the first length.

18. The semiconductor memory device according to claim 17, wherein
the first one of plate-like portion includes, in a core portion of the first one of plate-like portion, the insulating member continuously extending in the first direction at the position overlapping the stair portion in the stacking direction.

19. The semiconductor memory device according to claim 17, wherein
the first one of plate-like portion includes a plurality of plate-like conductive portions that are intermittently arranged in the first direction in the insulating member intermittently extending in the first direction, each of the plate-like conductive portions having a second length less than the first length in the first direction and penetrating the stacked body in the stacking direction.

20. The semiconductor memory device according to claim 17, wherein
the second one of plate-like portion includes, in a core portion of the second one of plate-like portion, the conductive member continuously extending, in the first direction and along a side surface of the stair portion, at least from a position of one end to a position of another end, in the first direction, of the stair portion.
